(19) United States
(12) Patent Application Publication
(10) Pub. No.: US 2006/0255376 A1
(43) Pub. Date: Nov. 16, 2006

(54) Integrated circuit and method for manufacturing an integrated circuit

(76) Inventors: Johann Tolonics, Heilbronn (DE); Klaus Locke, Wernau (DE); Peter Brandl, Villach (AT)

Correspondence Address: MCGRATH, GEISSLER, OLDS & RICHARDSON, PLLC, P.O. BOX 1364, FAIRFAX, VA, 22038-1364, US

(21) Appl. No.: 11/431,060

(22) Filed: May 10, 2006

(30) Foreign Application Priority Data
May 10, 2005 (DE) DE 10 2005 021450

(51) Int. Cl. H01L 29/80

(52) U.S. Cl. 257/273

(57) ABSTRACT

An integrated circuit is disclosed, the integrated circuit comprises: a vertically integrated bipolar transistor; and at least one emitter resistor, which is connected conductively to an emitter semiconductor region of the vertically integrated bipolar transistor. A collector semiconductor region, a base semiconductor region, and the emitter semiconductor region are placed vertically one over another at least in areas and formed as a single crystal. A resistance region of the emitter resistor is placed above the emitter semiconductor region and formed as a single crystal, and the resistance region, at least in areas, has a higher film resistance than the emitter semiconductor region.

This nonprovisional application claims priority under 35 U.S.C. § 119(a) on German Patent Application No. DE 10 2005 021 450, which was filed in Germany on May 10, 2005, and which is herein incorporated by reference.

### BACKGROUND OF THE INVENTION

1. Field of the Invention

The present invention relates to an integrated circuit and to a method for manufacturing an integrated circuit.

2. Description of the Background Art

It is known from the conventional art to connect an emitter of a bipolar transistor to a resistor in order to achieve a negative current feedback. To this end, the emitter of the bipolar transistor has, for example, a silicide layer, which, for example, is connected conductively to the resistor via metal tracks of a wiring plane.

This type of bipolar transistor is known from U.S. Pat. No. 6,177,717 B1. For the manufacture, an intrinsic collector of a vertical bipolar transistor is grown epitaxially on an extrinsic collector layer buried in a semiconductor substrate. A lateral isolation surrounds the upper part of the intrinsic collector. A silicon-germanium base lying above the intrinsic collector and above the lateral isolator is produced by differential epitaxy. An in-situ doped emitter is applied by epitaxy within a window above the base in such a way that the emitter region grows as single-crystal silicon in direct contact with the silicon of the base.

The in-situ doping of the growing emitter achieves that a higher dopant concentration is introduced into a lower region that is in contact with the base than into the upper region of the emitter. This makes it possible to achieve good silicidation of the upper surface of the single-crystal emitter. By variation of the dopant gas, a dopant concentration of 3×10²⁰/cm³ is achieved in the lower region and of 10²⁰/cm³ in the upper region of the emitter. Together with the silicidation (TiSi₂), a considerably lower emitter resistance in comparison with transistors can be achieved with polycrystalline emitters.

### SUMMARY OF THE INVENTION

It is therefore an object of the present invention to provide an integrated circuit with a bipolar transistor.

Accordingly, an integrated circuit is provided, which has a vertically integrated bipolar transistor and at least one emitter resistor, which is connected conductively to an emitter semiconductor region of the vertically integrated bipolar transistor. The emitter resistor is thereby conclusively defined by the conductive connection to the emitter of the bipolar transistor. Preferably, the emitter resistor in the integrated circuit functions as a negative current feedback, when the bipolar transistor is connected as an amplifier element.

According to the invention, a collector semiconductor region, a base semiconductor region, and the emitter semiconductor region are placed vertically one over another at least in areas and formed as a single crystal. Preferably, these semiconductor regions have a silicon crystal or a silicon-germanium mixed crystal, which are doped n-conductive and/or p-conductive corresponding to an npn transistor or a pnp transistor.

A resistance region of the emitter resistor is placed above the emitter semiconductor region and formed as a single crystal. Advantageously, the single-crystal resistance region is a silicon crystal lattice with dopants, which influence the conductivity of the emitter resistor.

Alternatively or in combination, the single-crystal resistance region may also have a mixed crystal, which has in addition to silicon, for example, germanium or carbon. Preferably, the crystal lattice of the emitter resistor continues the crystal lattice of the emitter semiconductor region.

According to an embodiment of the invention, the resistance region, at least in areas, has a film resistance greater by at least a factor of 10 than the emitter semiconductor region. The resistance region with the area with the higher film resistance is preferably made at a distance from the emitter semiconductor region. Advantageously, moreover, the resistance region is preferably made adjacent to the area to form a connecting region of the emitter resistor. The connecting region can have a silicide layer or a highly doped layer for a low-ohmic connection resistance, so that this exerts no significant effect on the emitter resistance value. Furthermore, the area of the resistance region is preferably at a distance from the emitter semiconductor region such that a space-charge region of the base-emitter diode advantageously does not extend into the area of the resistance region for all operating conditions.

An advantageous further embodiment of the invention provides that the emitter resistor has a dopant concentration profile, which effects a low-ohmic connection of the resistance region to the emitter semiconductor region. Preferably, the profile moreover effects a low-ohmic connection to at least one other component and/or a connection of the integrated circuit.

Two different embodiments of the invention provide that an area of the emitter resistor, particularly the resistance region, can have a silicon crystal with carbon and/or germanium. The carbon and germanium here can be incorporated, for example, into the silicon crystal lattice and change its resistance value locally.

An embodiment of the invention also provides that the resistance region can have a dopant concentration which is less than a tenth of the dopant concentration in the emitter semiconductor region. Thus, the conductance can be reduced in areas by the lower dopant concentration so that, for example, the vertical resistance region has, for example, a linearly or logarithmically increasing or decreasing resistance value from the wafer surface in the direction of the wafer depth.

Further, the bipolar transistor and the emitter resistor can be a component of a high-frequency circuit, particularly a high-frequency amplifier, the emitter resistor being connected as a negative current feedback.

In a further embodiment of the invention, at least one additional bipolar transistor can be provided, to which at least one additional emitter resistor is assigned. Here, the film resistance of the additional emitter resistor differs significantly from the other film resistance, whereby the at least two emitter resistors are processed on a wafer and the different film resistance is produced by masking.

A resistance base of the emitter resistor can lie within a transistor base of the bipolar transistor. In this case, a multitude of emitter fingers of the bipolar transistor can be provided, whereby one or more emitter resistors are connected conductively with each emitter finger.

Another aspect of the invention is a use of the previously described integrated circuit in a high-frequency device, particularly in a radar system or in a communication system, for example, in automotive engineering.

Another aspect of the invention is a method for manufacturing an integrated circuit. In this method, a vertically integrated bipolar transistor and at least one emitter resistor are produced, whereby the emitter resistor is connected conductively to an emitter semiconductor region of the vertically integrated bipolar transistor.

To produce the emitter resistor, a resistance region is applied as a single crystal over the emitter semiconductor region by selectively depositing the semiconductor material of the resistor region over the emitter semiconductor region. In so doing, the resistance region is applied epitaxially in such a way that the film resistance of the resistance region is greater than the film resistance of the emitter semiconductor region. Preferably, the film resistance of the resistance region is greater at least by a factor of 10 than the film resistance of the emitter semiconductor region. A highly doped connecting region can be applied in addition between the resistance region and the emitter semiconductor region.

A preferred further development of this embodiment of the invention provides that the resistance region during the epitaxy in situ is doped at least in areas with a dopant concentration lower by at least a factor of 10.

Alternatively, combinable method variants of the invention make it possible by the addition of GeH₄ gas during the epitaxy for germanium atoms to be introduced into the resistance region. Or the addition of methylsilane gas during the epitaxy makes it possible for carbon atoms to be introduced into the resistance region.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a schematic sectional view through a wafer with a vertically integrated bipolar transistor and a vertically integrated emitter resistor, and

FIG. 2 is a schematic dopant concentration course along section line A-A of FIG. 1.

### DETAILED DESCRIPTION

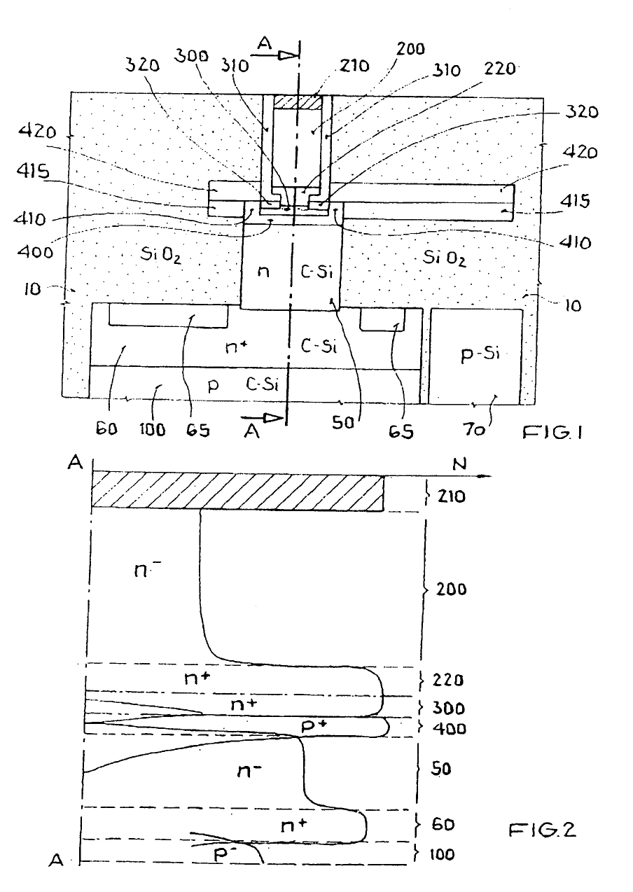

A heterobipolar transistor and an emitter resistor of an integrated circuit according to an embodiment of the present invention is shown as a sectional view through a processed wafer in FIG. 1.

A portion of a single-crystal, p-doped silicon substrate 100 is shown, on which a highly doped, buried layer 60 of the n-conductivity type is produced. A heterobipolar transistor is produced on a first area of buried layer 60 in the subsequent process steps. To isolate this heterobipolar transistor from other transistors or other components, trench isolations are provided, which are filled with polycrystalline silicon 70 or TEOS oxide. A buried silicide layer 65 of TiSi₂ is provided to connect buried layer 60.

A single-crystal collector semiconductor region 50, which has a lower dopant concentration than buried layer 60, is applied epitaxially on buried layer 60. Collector semiconductor region 50 is isolated laterally from other layers and components by a silicon dioxide dielectric 10.

Dielectric 10 also isolates a p-doped base semiconductor region 400, 410, 415. The areas 400 and 410 of the base semiconductor region are adjacent to collector semiconductor region 50 and are also formed as a single crystal, whereas the area of an extrinsic base 415 grows polycrystalline on dielectric 10. Base semiconductor region 400, 410, 415 is applied differentially and can have a silicon-germanium mixed crystal to form a heterojunction. To connect the extrinsic base with as low a resistance as possible, a silicide layer of TiSi₂ is adjacent to the base semiconductor region in the area of the extrinsic base. The metallic wiring of silicide layers 420, 65 of the extrinsic base and the buried layer are not shown in FIG. 1 for a simplified presentation.

n-Doped emitter semiconductor region 300 is adjacent to base semiconductor region 400 of the intrinsic base. An emitter resistor, which has three regions 220, 200, and 210, is adjacent to emitter semiconductor region 300 within two dielectrics 310, 320. The formation of the emitter resistor occurs by selectively growing epitaxially single-crystal silicon or a single-crystal silicon-germanium layer only within the emitter window formed by dielectrics 310, 320. Outside the window, no deposition occurs over the silicon oxide or silicon nitride regions 10. The starting point for this exemplary embodiment therefore is an exposed emitter window of the npn transistor, the remaining regions at least of the npn transistor being covered with an oxide or nitride layer 10.

The wafer is first precleaned with hydrofluoric acid-containing cleaning solution and by subsequent drying with isopropanol of the wafer. Next, the wafer is loaded into the epitaxy reactor, whereby a multiple nitrogen rinsing and evacuation cycle occurs to reduce surface contaminations.

This is followed by a hydrogen tempering at 750° C. to 900° C., whereby the residual native oxide is eliminated in the emitter window and desorption of hydrocarbons occurs. The hydrogen tempering in the epitaxy reactor produces a crystallographically clean silicon surface. During operation of the npn transistor, injection of minority charge carriers into the emitter is reduced because there is no interfering boundary layer to the emitter resistor. This enables significant improvement of the stability of the circuit electrical parameters.

Again after this, a selective, in situ-doped epitaxial deposition of silicon or silicon and germanium occurs, which initially form a single-crystal layer 220 with a high doping. This layer is a connecting region 220 between resistance region 200 and emitter semiconductor region 300. Preferably, without interruption of the epitaxy process, a resistance region 200 of the emitter resistor is also applied epitaxially, so that resistance region 200 is formed as a single-crystal, silicon-containing structure.

The emitter resistor is adjusted by a thickness of the epitaxial layer and/or by the concentration and/or the concentration course of the doping of this resistance region 200. For example, a retrograde dopant profile can be adjusted by a variable doping gas flow. A defined amount of germanium can be incorporated into the silicon crystal lattice by the addition of GeH₄ gas. In regions 210, 220 of the emitter resistor, the incorporation of germanium can be utilized to increase the solubility and activation limit for dopants, so that the resistance of the epitaxial layer in these regions is reduced. In order to reduce the junction resistance, it is possible to increase significantly the dopant concentration in connecting region 220 by adding germanium.

Carbon can be incorporated into the silicon crystal lattice of resistance region 200 by addition of methylsilane gas, to change the electrical properties of the bipolar transistor-emitter resistor arrangement. The resistance value can therefore be adjusted without changes in the layout and lithography masks being necessary. This exemplary embodiment thereby results in a greater flexibility for the circuit design with bipolar power transistors.

Resistance region 200 in the exemplary embodiment of FIG. 1 is connected by a silicide layer 210 with TiSi₂ for a low-ohmic contact resistance. Alternatively, a highly doped single-crystal or amorphous semiconductor layer can be used for low-ohmic connection.

This exemplary embodiment makes it possible to conserve chip area and to reduce the design effort for the layout by integrating a vertical resistor as an emitter resistor into the emitter structure of the bipolar transistor. The reduction of the emitter array area results in lower parasitic capacitances, and higher limiting frequencies, particularly for power heterobipolar transistors, are thereby possible.

FIG. 2 shows schematically the dopant distribution along the line A-A drawn in FIG. 1. In this case, semiconductor layer 50 forms the n⁻-doped collector with an n⁺ highly doped subcollector 60. Base semiconductor region 400 of the intrinsic base is p⁺ highly doped. Silicon semiconductor region 300 of the emitter, which is also n⁺-doped, is adjacent to base semiconductor region 400. In order to minimize a reactive effect of the emitter resistor on emitter semiconductor region 300, the emitter resistor has a connecting region 220, which is also n⁺-doped, adjacent to emitter semiconductor region 300. In particular, there is no boundary layer between emitter semiconductor region 300 and connecting region 220, which could influence the charge carrier motion.

A resistance region 200 of the emitter resistor with a low n⁻ doping, which influences or totally determines the resistance value of resistance region 200, is adjacent to connecting region 220. Furthermore, the emitter resistor has a connecting layer 210, which is a silicide layer in the exemplary embodiment shown in FIG. 2. This type of connecting layer 210 makes it possible to connect the emitter resistor to another component or to a connection of the integrated circuit. Alternatively, connecting layer 210 can be highly n⁺-doped in order to achieve a low connection resistance.

Because the emitter resistor is directly adjacent to the emitter, moreover, a direct thermal coupling is possible, which is substantially improved compared with an indirect thermal coupling via a metallization structure. Local heating of an emitter finger, therefore, leads to direct heating of the adjacent resistance area 200, as a result of which the conductivity of resistance area 200 is reduced. The reduction of the conductivity results in an increasing negative current feedback, so that the local current flow in the heated emitter finger is reduced.

A uniform current distribution within the emitter finger array is assured by the bipolar transistor-emitter resistor structure of this exemplary embodiment, so that the failure rate of the integrated circuit can be reduced.

The emitter resistor is adjusted by technological parameters, such as the thickness of epitaxially grown resistance region 200, the dopant concentration profile, or the concentration of foreign elements in resistance region 200. The resistance value of resistance region 200 can be slightly influenced by the layout geometry of resistance region 200.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An integrated circuit comprising
a vertically integrated bipolar transistor; and
at least one emitter resistor, which is connected conductively to an emitter semiconductor region of the vertically integrated bipolar transistor,
wherein a collector semiconductor region, a base semiconductor region, and the emitter semiconductor region are structured, at least partially, vertically over one another and are formed as a single crystal,
wherein a resistance region of the emitter resistor is provided above the emitter semiconductor region and formed as a single crystal, and
wherein the resistance region, at least in areas, has a higher film resistance than the emitter semiconductor region.

2. The integrated circuit according to claim 1, wherein the film resistance of the resistance region is greater at least by a factor of 10 than the film resistance of the emitter semiconductor region.

3. The integrated circuit according to claim 1, wherein the emitter resistor has a dopant concentration profile, which effects a low-ohmic connection of the resistance region to the emitter semiconductor region by a connecting region.

4. The integrated circuit according to claim 1, wherein the resistance region has silicon crystal with carbon.

5. The integrated circuit according to claim 1, wherein a region of the emitter resistor has silicon crystal with germanium.

6. The integrated circuit according to claim 1, wherein the resistance region has a dopant concentration that is lower than a dopant concentration in the emitter semiconductor region.

7. The integrated circuit according to claim 6, wherein the dopant concentration in the resistance region is less than one tenth of the dopant concentration in the emitter semiconductor region.

8. The integrated circuit according to claim 1, wherein a connecting region of the emitter resistor has a highly doped semiconductor region.

9. The integrated circuit according to claim 1, wherein a connecting region of the emitter resistor has a silicide layer.

10. The integrated circuit according to claim 1, wherein the emitter resistor is connected as a negative current feedback.

11. The integrated circuit according to claim 1, further comprising at least one additional bipolar transistor to which at least one additional emitter resistor is assigned, wherein the film resistance of the additional emitter resistor differs from the other film resistance.

12. The integrated circuit according to claim 1, wherein a resistance base of the emitter resistor lies within a transistor base of the bipolar transistor on the wafer.

13. The integrated circuit according to claim 1, wherein the integrated circuit is a component in a high-frequency device, in a radar system, or in a communication system.

14. A method for manufacturing an integrated circuit, the method comprising the steps of:
providing a vertically integrated bipolar transistor; and
providing at least one emitter resistor, which is connected conductively to an emitter semiconductor region of the vertically integrated bipolar transistor;
wherein the emitter resistor is formed by the steps comprising:
applying a resistance region as a single crystal over the emitter semiconductor region by selectively depositing epitaxially the semiconductor material of the resistance region over the emitter semiconductor region; and
applying the resistance region epitaxially so that a film resistance of the resistance region is greater than a film resistance of the emitter semiconductor region.

15. The method according to claim 14, wherein the resistance region during the epitaxy in situ is doped at least in areas with a lower dopant concentration than the emitter semiconductor region.

16. The method according to claim 14, wherein germanium atoms are introduced into a region of the emitter resistor by adding GeH₄ gas during the epitaxy.

17. The method according to claim 14, wherein carbon atoms are introduced into the resistance region by adding methylsilane gas during the epitaxy.
